(19) United States
(12) Patent Application Publication
(10) Pub. No.: US 2015/0340660 A1
(43) Pub. Date: Nov. 26, 2015

(54) ORGANIC ELECTROLUMINESCENT DEVICE, ILLUMINATION APPARATUS, AND ILLUMINATION SYSTEM

(71) Applicant: Kabushiki Kaisha Toshiba, Tokyo (JP)

(72) Inventors: Atsushi WADA, Kawasaki (JP); Tomio ONO, Yokohama (JP); Tomoaki SAWABE, Tokyo (JP)

(73) Assignee: Kabushiki Kaisha Toshiba, Tokyo (JP)

(21) Appl. No.: 14/811,877

(22) Filed: Jul. 29, 2015

Related U.S. Application Data
(63) Continuation of application No. PCT/JP2013/077657, filed on Oct. 10, 2013.

(30) Foreign Application Priority Data
Feb. 4, 2013 (JP) 2013-019965

(51) Int. Cl. H01L 51/52; H05B 33/08; H01L 51/00

(52) U.S. Cl. CPC H01L 51/5268; H01L 51/0096; H01L 51/5215; H01L 51/5221; H05B 33/0896; H01L 2251/5361

(57) ABSTRACT

An organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The second substrate includes a light scattering part overlapping with the conductive part when projected onto a plane perpendicular to the stacking direction.

### CROSS-REFERENCE TO RELATED APPLICATIONS

This is a continuation application of International Application PCT/JP2013/077657, filed on Oct. 10, 2013; the entire contents of which are incorporated herein by reference.

### FIELD

Embodiments described herein relate generally to an organic electroluminescent device, an illumination apparatus, and an illumination system.

### BACKGROUND

There is an organic electroluminescent device that includes a light transmissive first electrode, a second electrode, and an organic light emitting layer provided between the first electrode and the second electrode. There is an illumination apparatus using the organic electroluminescent device as a light source. There is an illumination system that includes a plurality of organic electroluminescent devices and a controller configured to control turning on and off of the plurality of organic electroluminescent devices. The organic electroluminescent device is made to be light transmissive by using a thin-line shaped second electrode in which a plurality of openings are provided, or using a light transmissive second electrode. An improvement in the visibility of a transmission image is desired in such an organic electroluminescent device.

### BRIEF DESCRIPTION OF THE DRAWINGS

FIG. 1 is a schematic cross-sectional view showing an organic electroluminescent device according to a first embodiment;

FIG. 2 is a schematic plan view showing part of the organic electroluminescent device according to the first embodiment;

FIG. 3 is a schematic cross-sectional view showing part of the organic electroluminescent device according to the first embodiment;

FIGS. 4A to 4D are schematic cross-sectional views showing other organic electroluminescent devices according to the first embodiment;

FIG. 5 is a schematic plan view showing part of another organic electroluminescent device according to the first embodiment;

FIGS. 6A and 6B are schematic cross-sectional views showing other organic electroluminescent devices according to the first embodiment;

FIG. 7 is a schematic cross-sectional view showing another organic electroluminescent device according to the first embodiment;

FIGS. 8A and 8B are schematic cross-sectional views showing other organic electroluminescent devices according to the first embodiment;

FIGS. 9A and 9B are schematic views showing another organic electroluminescent device according to the first embodiment;

FIGS. 10A and 10B are schematic cross-sectional views showing other organic electroluminescent devices according to the first embodiment;

FIGS. 11A and 11B are schematic diagrams showing another organic electroluminescent device according to the first embodiment;

FIGS. 12A and 12B are schematic cross-sectional views showing other organic electroluminescent devices according to the first embodiment;

FIG. 13 is a schematic diagram showing an illumination apparatus according to a second embodiment; and

FIGS. 14A and 14B are schematic diagrams showing an illumination system according to a third embodiment.

### DETAILED DESCRIPTION

According to one embodiment, an organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The second substrate includes a light scattering part overlapping with the conductive part when projected onto a plane perpendicular to the stacking direction.

According to another embodiment, an organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The conductive part includes a light scattering part facing the second substrate.

According to another embodiment, an organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The wiring layer is provided between the first electrode and the organic light emitting layer. The second substrate includes a light scattering part overlapping with the wiring part when projected onto a plane perpendicular to the stacking direction.

According to another embodiment, an organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The wiring layer is provided between the first electrode and the organic light emitting layer. The wiring part includes a light scattering part facing the second substrate.

According to another embodiment, an organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The second electrode is disposed between the wiring layer and the organic light emitting layer. The second substrate includes a light scattering part overlapping with the wiring part when projected onto a plane perpendicular to the stacking direction.

According to another embodiment, an organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The second electrode is disposed between the wiring layer and the organic light emitting layer. The wiring part includes a light scattering part facing the second substrate.

According to another embodiment, an illumination apparatus includes an organic electroluminescent device and a power source. The organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The power source is electrically connected to the first electrode and the second electrode and supplies a current to the organic light emitting layer via the first electrode and the second electrode. The second substrate includes a light scattering part overlapping with the conductive part when projected onto a plane perpendicular to the stacking direction.

According to another embodiment, an illumination apparatus includes an organic electroluminescent device and a power source. The organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The power source is electrically connected to the first electrode and the second electrode and supplies a current to the organic light emitting layer via the first electrode and the second electrode. The conductive part includes a light scattering part facing the second substrate.

According to another embodiment, an illumination apparatus includes an organic electroluminescent device and a power source. The organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The wiring layer is provided between the first electrode and the organic light emitting layer. The power source is electrically connected to the first electrode and the second electrode and supplies a current to the organic light emitting layer via the first electrode and the second electrode. The second substrate includes a light scattering part overlapping with the wiring part when projected onto a plane perpendicular to the stacking direction.

According to another embodiment, an illumination apparatus includes an organic electroluminescent device and a power source. The organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The wiring layer is provided between the first electrode and the organic light emitting layer. The power source is electrically connected to the first electrode and the second electrode and supplies a current to the organic light emitting layer via the first electrode and the second electrode. The wiring part includes a light scattering part facing the second substrate.

According to another embodiment, an illumination apparatus includes an organic electroluminescent device and a power source. The organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The second electrode is disposed between the wiring layer and the organic light emitting layer. The power source is electrically connected to the first electrode and the second electrode and supplies a current to the organic light emitting layer via the first electrode and the second electrode. The second substrate includes a light scattering part overlapping with the wiring part when projected onto a plane perpendicular to the stacking direction.

According to another embodiment, an illumination apparatus includes an organic electroluminescent device and a power source. The organic electroluminescent device includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The second electrode is disposed between the wiring layer and the organic light emitting layer. The power source is electrically connected to the first electrode and the second electrode and supplies a current to the organic light emitting layer via the first electrode and the second electrode. The wiring part includes a light scattering part facing the second substrate.

According to another embodiment, an illumination system includes a plurality of organic electroluminescent devices and a controller. Each of the organic electroluminescent devices includes a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The controller is electrically connected to each of the organic electroluminescent devices and controlling turning on and off of each of the organic electroluminescent devices. The second substrate includes a light scattering part overlapping with the conductive part when projected onto a plane perpendicular to the stacking direction.

According to another embodiment, an illumination system includes a plurality of organic electroluminescent devices and a controller. Each of the organic electroluminescent devices a first substrate, a second substrate, and a stacked body. The first substrate has light permeability. The second substrate has light permeability. The stacked body is provided between the first substrate and the second substrate. The stacked body includes a first electrode, a second electrode, and an organic light emitting layer. The first electrode has light permeability. The second electrode includes an opening and a conductive part. The conductive part is light reflective. The second electrode is stacked on the first electrode in a stacking direction of the first substrate and the second substrate. The organic light emitting layer is provided between the first electrode and the second electrode. The controller is electrically connected to each of the organic electroluminescent devices and controlling turning on and off of each of the organic electroluminescent devices. The conductive part includes a light scattering part facing the second substrate.

According to another embodiment, an illumination system includes a plurality of organic electroluminescent devices and a controller. Each of the organic electroluminescent devices includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The wiring layer is provided between the first electrode and the organic light emitting layer. The controller is electrically connected to each of the organic electroluminescent devices and controlling turning on and off of each of the organic electroluminescent devices. The second substrate includes a light scattering part overlapping with the wiring part when projected onto a plane perpendicular to the stacking direction.

According to another embodiment, an illumination system includes a plurality of organic electroluminescent devices and a controller. Each of the organic electroluminescent devices includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The wiring layer is provided between the first electrode and the organic light emitting layer. The controller is electrically connected to each of the organic electroluminescent devices and controlling turning on and off of each of the organic electroluminescent devices. The wiring part includes a light scattering part facing the second substrate.

According to another embodiment, an illumination system includes a plurality of organic electroluminescent devices and a controller. Each of the organic electroluminescent devices includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The second electrode is disposed between the wiring layer and the organic light emitting layer. The controller is electrically connected to each of the organic electroluminescent devices and controlling turning on and off of each of the organic electroluminescent devices. The second substrate includes a light scattering part overlapping with the wiring part when projected onto a plane perpendicular to the stacking direction.

According to another embodiment, an illumination system includes a plurality of organic electroluminescent devices and a controller. Each of the organic electroluminescent devices includes a first substrate, a second substrate, and a stacked body. The first substrate has light permeability. The second substrate has light permeability. The stacked body is provided between the first substrate and the second substrate. The stacked body includes a first electrode, a second electrode, an organic light emitting layer, and a wiring layer. The first electrode has light permeability. The second electrode is stacked on the first electrode in a stacking direction of the first substrate and the second substrate. The second electrode has light permeability. The organic light emitting layer is provided between the first electrode and the second electrode. The wiring layer includes an opening and a wiring part. The wiring part is light reflective. The second electrode is disposed between the wiring layer and the organic light emitting layer. The controller is electrically connected to each of the organic electroluminescent devices and controlling turning on and off of each of the organic electroluminescent devices. The wiring part includes a light scattering part facing the second substrate.

Various embodiments will be described hereinafter with reference to the accompanying drawings.

The drawings are schematic or conceptual; and the relationships between the thicknesses and the widths of portions, the proportions of sizes between portions, etc., are not necessarily the same as the actual values thereof. Also, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

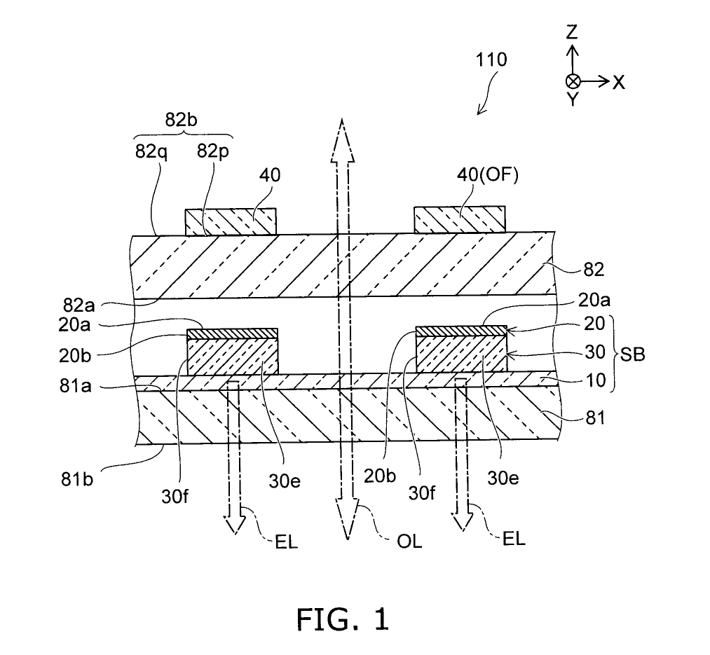

FIG. 1 is a schematic cross-sectional view showing an organic electroluminescent device according to a first embodiment.

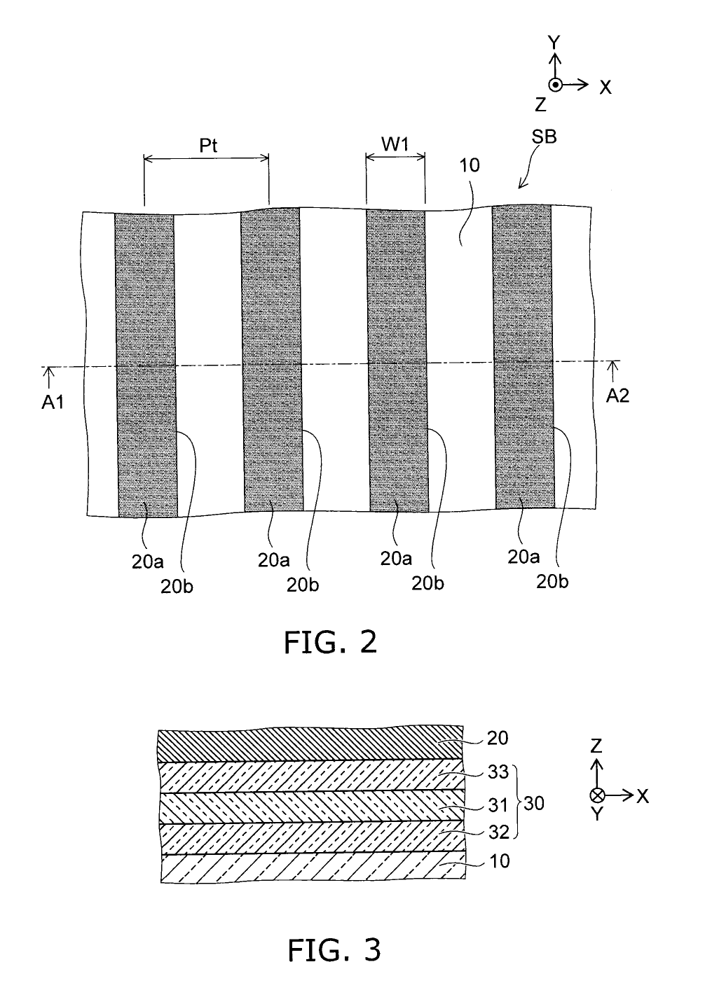

FIG. 2 is a schematic plan view showing part of the organic electroluminescent device according to the first embodiment.

FIG. 1 is an A1-A2 line cross-sectional view of FIG. 2. These views illustrate part of the organic electroluminescent device according to the embodiment in enlarged views.

As shown in FIG. 1 and FIG. 2, an organic electroluminescent device 110 includes a first substrate 81, a second substrate 82, and a stacked body SB.

The first substrate 81 has light permeability. The second substrate 82 is disposed facing the first substrate 81. The second substrate 82 has light permeability. The stacked body SB is provided between the first substrate 81 and the second substrate 82. Namely, the stacked body SB is provided on the first substrate 81 and the second substrate 82 is provided on the stacked body SB.

Here, a direction parallel to the stacking direction of the first substrate 81 and the second substrate 82 is set to be a Z-axis direction. One of directions perpendicular to the Z-axis direction is set to be an X-axis direction. A direction perpendicular to the X-axis direction and the Z-axis direction is set to be a Y-axis direction.

The first substrate 81 has a first major surface 81a and a second major surface 81b. The first major surface 81a is, for example, a plane perpendicular to the Z-axis direction. The second major surface 81b is a face opposite to the first major surface 81a. The second major surface 81b is, for example, parallel to the first major surface 81a. The second substrate 82 has a third major surface 82a and a fourth major surface 82b. The third major surface 82a is a face facing the first major surface 81a. The fourth major surface 82b is a face opposite to the third major surface 82a. The fourth major surface 82b is, for example, parallel to the third major surface 82a. The third major surface 82a and the fourth major surface 82b are, for example, parallel to the first major surface 81a.

The stacked body SB is provided on the first major surface 81a. The second substrate 82 is provided on the stacked body SB. A predetermined interval is provided between the first substrate 81 and the second substrate 82. An interval in the Z-axis direction between the first substrate 81 and the second substrate 82 is specified by a spacer, not shown schematically, a frame-shaped protruding part that is provided at an outer edge of the second substrate 82, or the like.

The interval in the Z-axis direction between the first substrate 81 and the second substrate 82 is greater than a thickness (length in the Z-axis direction) of the stacked body SB. Because of this, a predetermined interval is provided between the stacked body SB and the second substrate 82. At the outer edge of the first substrate 81 and the second substrate 82, a sealing member, such as an ultraviolet curing resin, is provided.

The sealing member fills a gap between the first substrate 81 and the second substrate 82 at the outer edge part of the first substrate 81 and the second substrate 82 and bonds the first substrate 81 and the second substrate 82. Because of this, the stacked body SB is sealed by the first substrate 81 and the second substrate 82. For example, the stacked body SB is protected from moisture or the like.

A space between the stacked body SB and the second substrate 82 is filled with, for example, an inert gas or the like. A desiccating agent or the like may be provided between the stacked body SB and the second substrate 82. The space between the stacked body SB and the second substrate 82 may be, for example, an air layer. For example, the degree of vacuum may be increased in the space between the stacked body SB and the second substrate 82. The space between the stacked body SB and the second substrate 82 may be filled with, for example, a liquid acrylic resin, an epoxy resin, and the like. Calcium oxide, barium oxide, and the like may be added, as a desiccating agent, to the acrylic resin or epoxy resin.

The stacked body SB includes a first electrode 10, a second electrode 20, and an organic light emitting layer 30. The first electrode 10 has light permeability. The first electrode 10 is, for example, a transparent electrode. The second electrode 20 is stacked on the first electrode 10 in the Z-axis direction. The organic light emitting layer 30 is provided between the first electrode 10 and the second electrode 20. In this example, the first electrode 10, the organic light emitting layer 30, and the second electrode 20 are stacked in this order. The first electrode 10 is provided on the first major surface 81a of the first substrate 81. The organic light emitting layer 30 is provided on the first electrode 10. The second electrode 20 is provided on the organic light emitting layer 30.

The organic light emitting layer 30 has, for example, a plurality of light emitting parts 30e and a plurality of openings 30f. Each of the plurality of light emitting parts 30e extends in the Y-axis direction and is arranged side by side in the X-axis direction. Each of the plurality of openings 30f is disposed between each of the plurality of light emitting parts 30e. In this example, each of the plurality of openings 30f has the shape of a groove extending in the Y-axis direction. Each of the plurality of openings 30f extends in the Y-axis direction and is arranged side by side in the X-axis direction.

The second electrode 20 has a conductive part 20a and an opening 20b. In this example, the second electrode 20 has a plurality of conductive parts 20a and a plurality of openings 20b. Each of the plurality of conductive parts 20a extends in the Y-axis direction and is arranged side by side in the X-axis direction. Each of the plurality of conductive parts 20a is disposed on each of the plurality of light emitting parts 30e.

Each of the plurality of openings 20b is disposed between each of the plurality of conductive parts 20a. In this example, each of the plurality of openings 20b has the shape of a groove extending in the Y-axis direction. Each of the plurality of openings 20b extends in the Y-axis direction and is arranged side by side in the X-axis direction. Each of the plurality of openings 20b is disposed, for example, on each of the plurality of openings 30f. In this example, the second electrode 20 and the light emitting layer 30 have the shape of a stripe.

The conductive part 20a has light reflective properties. A light reflectance of the conductive part 20a is, for example, higher than a light reflectance of the first electrode 10. In the specification of the application, a state of having a light reflectance higher than the light reflectance of the first electrode 10 is referred to as light reflective properties.

The second substrate 82 has a light scattering part 40. The light scattering part 40, for example, scatters incident light. The light scattering part 40, for example, changes the direction of travel of incident light. The light scattering part 40 is disposed in a position that overlaps with the conductive part 20a when being projected onto the X-Y plane. The light scattering part 40 is provided, for example, merely in the portion that overlaps with the conductive part 20a when being projected onto the X-Y plane. In this example, the second substrate 82 has a plurality of light scattering parts 40. Each of the plurality of light scattering parts 40 is disposed in a position that overlaps with each of the plurality of conductive parts 20a. The shape of each of the plurality of light scattering parts 40 projected onto the X-Y plane is substantially the same as the shape of each of the plurality of conductive part 20a projected onto the X-Y plane. Namely, in this example, each of the plurality of light scattering parts 40 extends in the Y-axis direction. Each of the plurality of light scattering parts 40 extends in the Y-axis direction and is arranged side by side in the X-axis direction.

In this example, each of the plurality of light scattering parts 40 is provided on the fourth major surface 82b. The fourth major surface 82b includes an overlapping part 82p that overlaps with the conductive part 20a when being projected onto the X-Y plane and a non-overlapping part 82q that does not overlap with the conductive part 20a when being projected onto the X-Y plane. In this example, the fourth major surface 82b includes a plurality of overlapping parts 82p that overlap with each of the plurality of conductive parts 20a when being projected onto the X-Y plane and a plurality of non-overlapping parts 82q that do not overlap with each of the plurality of conductive parts 20a when being projected onto the X-Y plane. Each of the plurality of light scattering parts 40 is provided on each of the plurality of overlapping parts 82p. Each of the plurality of light scattering parts 40 is provided, for example, merely on each of the plurality of overlapping parts 82p. Light scattering properties of the light scattering part 40 are, for example, higher than light scattering properties of the non-overlapping part 82q of the fourth major surface 82b.

In this example, each of the plurality of light scattering parts 40 is, for example, an optical film OF having light permeability and light scattering properties. For example, the optical film OF is pasted onto the overlapping part 82p of the fourth major surface 82b. Because of this, the light scattering part 40 is provided on the second substrate 82. A thin film having a fine structure such as a microlens sheet and a lenticular lens sheet is used as the optical film OF.

The organic light emitting layer 30 is electrically connected to the first electrode 10. Each of the plurality of light emitting parts 30e of the organic light emitting layer 30 makes contact with, for example, the first electrode 10. Because of this, the organic light emitting layer 30 is electrically connected to the first electrode 10.

The organic light emitting layer 30 is electrically connected to the second electrode 20. The organic light emitting layer 30 makes contact with, for example, each of the plurality of conductive parts 20a. Because of this, the organic light emitting layer 30 is electrically connected to the second electrode 20. In the specification of the application, “electrically connected” includes the case where another conductive member is interposed in between, in addition to the case of direct contact.

A current is caused to flow through the organic light emitting layer 30 by using the first electrode 10 and the second electrode 20. Because of this, the organic light emitting layer 30 emits light. For example, when a current flows, the organic light emitting layer 30 recombines an electron and a hole, and generates an exciton. The organic light emitting layer 30 emits light by, for example, utilizing the discharge of light when the exciton is deactivated by radiation.

In the organic electroluminescent device 110, each of the plurality of light emitting parts 30e of the organic light emitting layer 30 serves as an emission area. Emission light EL emitted from each of the plurality of light emitting parts 30e is emitted to the outside of the organic electroluminescent device 110 via the first electrode 10. A part of the emission light EL is reflected from the conductive part 20a of the second electrode 20 and is emitted to the outside via the organic light emitting layer 30 and the first electrode 10. Namely, the organic electroluminescent device 110 is of a single-sided light emission type.

Furthermore, in the organic electroluminescent device 110, outside light OL that enters from the outside passes through the first electrode 10 at the portion between each of the plurality of conductive parts 20a. As described above, the organic electroluminescent device 110 causes the outside light OL that enters the organic electroluminescent device 110 from the outside to pass through while emitting the emission light EL. As described above, the organic electroluminescent device 110 has light permeability in a turned-off state. Also in a turned-on state, when observed from the side of the second electrode 20, the organic electroluminescent device 110 has light permeability. Because of this, in the organic electroluminescent device 110, it is possible to visually recognize the image of the background through the organic electroluminescent device 110. Namely, the organic electroluminescent device 110 is a light source that can be seen through and which has the shape of a thin film or the shape of a plate.

As described above, according to the organic electroluminescent device 110 of the embodiment, it is possible to provide a light transmissive organic electroluminescent device. In the case where the organic electroluminescent device 110 is applied to an illumination apparatus, various new applications are enabled due to the function that causes the background image to pass through, in addition to the illumination function.

The light transmissive organic electroluminescent device has a configuration of not having the light scattering part 40. With such a configuration, for example, when a transmitted image is observed from the side of the second substrate 82, there is a case where it becomes difficult to view the transmitted image. In the case where the light transmissive organic electroluminescent device does not have the light scattering part 40, part of the outside light OL that enters from the side of the second substrate 82 is reflected from the conductive part 20a and is emitted again to the outside from the second substrate 82. This reflected light overlaps with the transmitted image. Because of this, it becomes difficult to view the transmitted image.

In contrast to this, in the organic electroluminescent device 110 according to the embodiment, at least part of the light that enters from the side of the second substrate 82 and is reflected from the conductive part 20a scatters at the light scattering part 40. For example, entering of the light reflected from the conductive part 20a to the eyes of an observer is suppressed. The light scattering part 40 functions as, for example, an antireflection film that suppresses the light reflected from the conductive part 20a. On the other hand, the transmitted image passes through, for example, the portion between each of the plurality of light scattering parts 40 and enters the eyes of an observer. Because of this, in the organic electroluminescent device 110, it is possible to enhance the visibility of a transmitted image.

For example, there is a configuration in which a black pigment, such as black chromium oxide, is used as an antireflection film. However, a black pigment containing chromium oxide or the like is detrimental to environment. Furthermore, for example, there is a configuration in which reflection is prevented by the effect of light interference obtained by stacking a translucent reflection layer and a transparent layer. However, if a stacked layer is formed by stacking a translucent reflection layer and a transparent layer, for example, manufacturing takes time.

In contrast to this, in the organic electroluminescent device 110, for example, reflected light is suppressed by the light scattering part 40 using the optical film OF or the like. The light scattering part 40 does not contain a harmful substance such as chromium oxide. Because of this, it is possible to suppress lowering of the environmental resistance. Further, in the organic electroluminescent device 110, it is possible to form the light scattering part 40 by, for example, 3o pasting the optical film OF. Because of this, in the organic electroluminescent device 110, it is possible to form a structure that suppresses reflected light comparatively easily. For example, it is possible to suppress prolongation of the manufacturing time.

FIG. 3 is a schematic cross-sectional view showing part of the organic electroluminescent device according to the first embodiment.

As shown in FIG. 3, the organic light emitting layer 30 includes a first layer 31. It is possible for the organic light emitting layer 30 to further include at least one of a second layer 32 and a third layer 33 as appropriate. The first layer 31 discharges light including wavelengths of visible light. The second layer 32 is provided between the first layer 31 and the first electrode 10. The third layer 33 is provided between the first layer 31 and the second electrode 20.

For example, a material such as Alq₃ (tris(8-hydroxyquinolinolato)aluminum), F8BT (poly(9,9-dioctylfluorene-co-benzothiadiazole) or PPV (poly(p-phenylenevinylene)) can be used for the first layer 31. A mixing material of a host material and a dopant added to the host material can be used for the first layer 31. As the host material, for example, CBP (4,4′-N,N′-bis(dicarbazolyl-biphenyl)), BCP (2,9-dimethyl-4,7-diphenyl-1,10-phenanthroline), TPD (4,4′-bis-N-3-methylphenyl-N-phenylaminobiphenyl), PVK (polyvinyl carbazole), PPT (poly(3-phenylthiophene)) or the like can be used as the host material. For example, Flrpic (iridium (III) bis(4,6-di-fluorophenyl)-pyridinate-N,C2′-picolinate), Ir(ppy)₃ (tris (2-phenylpyridine)iridium), Flr6 (bis(2,4-difluorophenylpyridinate)-tetrakis(1-pyrazolyl)borate-iridium(III)) or the like can be used as a dopant material. The first layer is not limited to layers formed of these materials.

The second layer 32 functions as, for example, a hole injection layer. The hole injection layer includes at least any of, for example, PEDPOT: PPS (poly(3,4-ethylenedioxythiophene)-poly(styrenesulfonate)), CuPc (copper phthalocyanine), MoO₃ (molybdenumtrioxide), and the like. The second layer 32 functions as, for example, a hole transport layer. The hole transport layer includes at least any of, for example, a-NPD (4,4′-bis[N-(1-naphthyl)-N-phenylamino]biphenyl), TAPC (1,1-bis[4-[N,N-di(p-tolyl)amino]phenyl]cyclohexane), m-MTDATA (4,4′,4″-tris[phenyl(m-tolyl)amino]triphenylamine), TPD (bis(3-methylphenyl)-N,N′-diphenylbenzidine), TCTA (4,4′,4″-tri(N-carbazolyl)triphenylamine), and the like. The second layer 32 may have a stacked structure, for example, of a layer functioning as a hole injection layer and a layer functioning as a hole transport layer. The second layer 32 may include a layer other than the layer functioning as a hole injection layer and a layer functioning as a hole transport layer. The second layer 32 is not limited to layers formed of these materials.

The third layer 33 may include a layer functioning as, for example, an electron injection layer. The electron injection layer includes at least any of, for example, lithium fluoride, cesium fluoride, lithium quinoline complex, and the like. The third layer 33 can include a layer functioning as, for example, an electron transport layer. The electron transport layer includes at least any of, for example, Alq3 (tris(8-quinolinolate)aluminum (III)), BAIq (bis(2-methyl-8-quinolilate)(p-phenylphenolate)aluminum), Bphen (bathophenanthroline), 3TPYMB (tris[3-(3-pyridyl)-mesityl]borane), and the like. The third layer 33 may have a stacked structure, for example, of a layer functioning as an electron injection layer and a layer functioning as an electron transport layer. The third layer 33 may include a layer other than the layer functioning as an electron injection layer and a layer functioning as an electron transport layer. The third layer 33 is not limited to layers formed of these materials.

For example, the light emitted from the organic light emitting layer 30 is substantially white light. That is, the light emitted from the organic electroluminescent device 110 is white light. Here, “white light” is substantially white and also includes, for example, reddish, yellowish, greenish, bluish, and purplish white light.

The first electrode 10 contains an oxide containing at least one device selected from the group consisting of, for example, In, Sn, Zn and Ti. For example, a film of indium oxide, zinc oxide, tin oxide or indium tin oxide (ITO), a film manufactured using a conductive glass containing fluorine-doped tin oxide (FTO) or indium zinc oxide (such as NESA), gold, platinum, silver, copper or the like can be used for the first electrode 10. The first electrode 10 functions as, for example, an anode. The first electrode 10 is not limited to electrodes formed of these materials.

The second electrode 20 contains at least any of, for example, aluminum and silver. For example, an aluminum film is used for the second electrode 20. Furthermore, an alloy of silver and magnesium may be used for the second electrode 20. Calcium may be added to the alloy. The second electrode 20 functions as, for example, a cathode. The second electrode 20 is not limited to electrodes formed of these materials.

It may also be possible to cause the first electrode 10 to function as a cathode, the second electrode 20 as an anode, the second layer 32 as an electron injection layer or electron transport layer, and the third layer 33 as a hole injection layer or hole transport layer.

For example, a glass substrate, a resin substrate, or the like is used as the first substrate 81 and the second substrate 82.

A thickness (length in the Z-axis direction) of the first electrode 10 is, for example, not less than 10 nm and not more than 500 nm. Favorably, the thickness is not less than 50 nm and not more than 200 nm. A thickness of the organic light emitting layer 30 is, for example, not less than 50 nm and not more than 500 nm. A thickness of the second electrode 20 (the conductive part 20a) is, for example, not less than 10 nm and not more than 500 nm. A width W1 (length in the X-axis direction) of the conductive part 20a is, for example, not less than 1 μm and not more than 500 μm. A pitch Pt of the plurality of conductive parts 20a is, for example, not less than 2 μm and not more than 2,000 μm. The pitch Pt is, for example, a distance in the X-axis direction between centers in the X-axis direction of the two neighboring conductive parts 20a.

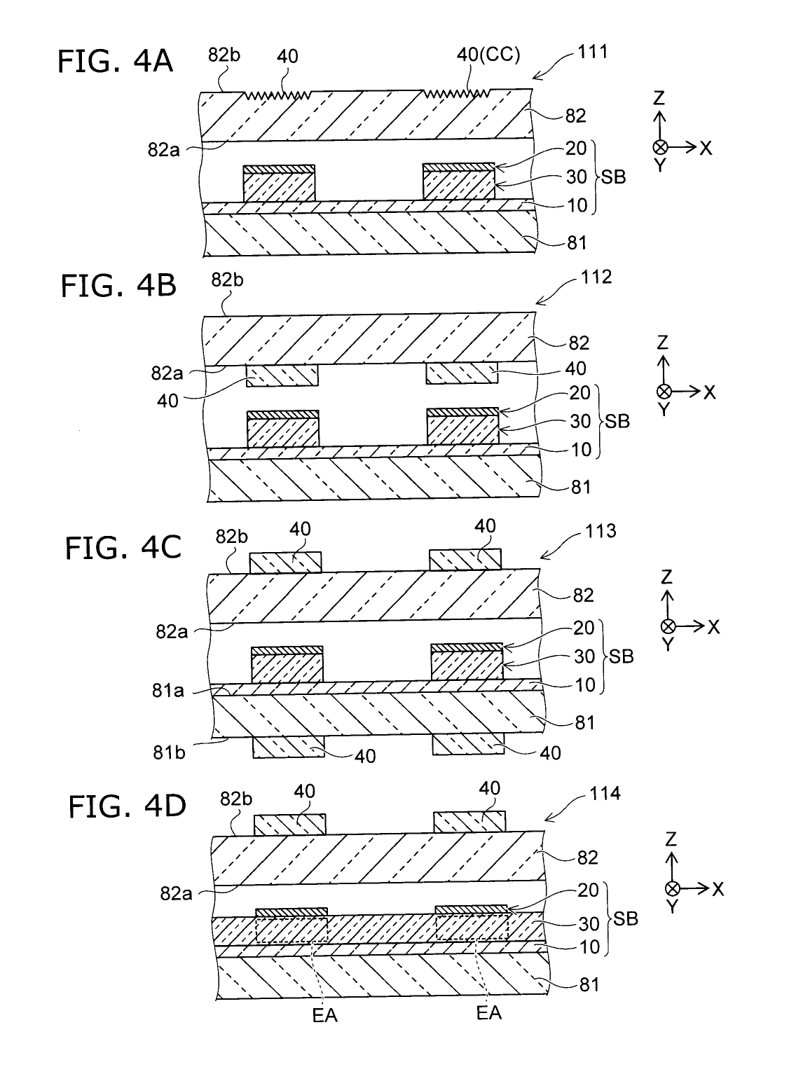

FIGS. 4A to 4D are schematic cross-sectional views showing other organic electroluminescent devices according to the first embodiment.

As shown FIG. 4A, in an organic electroluminescent device 111, the light scattering part 40 is a concave and convex part CC provided on the fourth major surface 82b itself of the second substrate 82. The concave and convex part CC has the shape of, for example, a pyramid, a prism, or the like. As described above, the light scattering part 40 may be, for example, the concave and convex part CC provided on the fourth major surface 82b itself. It is sufficient for the light scattering part 40 to have, for example, a plurality of fine structures scattering light. The concave and convex part CC may be formed by, for example, frost processing or the like.

As shown in FIG. 4B, in an organic electroluminescent device 112, the light scattering part 40 is provided on the third major surface 82a of the second substrate 82. As described above, the light scattering part 40 may be provided on the third major surface 82a. It is sufficient for the light scattering part 40 to be disposed in a position of the second substrate 82, which overlaps with the conductive part 20a when being projected onto the X-Y plane (when viewed in the Z-axis direction).

As shown in FIG. 4C, in an organic electroluminescent device 113, the light scattering part 40 is further provided on the second major surface 81b of the first substrate 81. The light scattering part 40 of the first substrate 81 is disposed in a position of the first substrate 81, which overlaps with the conductive part 20a when being projected onto the X-Y plane. As described above, the light scattering part 40 may further be provided on the first substrate 81. In this case, for example, it is also possible to enhance the visibility of a transmitted image viewed from the side of the first substrate 81. Furthermore, the light scattering part 40 provided on the second major surface 81b of the first substrate 81 suppresses total reflection of the emission light EL from the second major surface 81b. Because of this, in the case where the light scattering part 40 is further provided on the first substrate 81, for example, it is also possible to enhance light extraction efficiency of the emission light EL.

As shown in FIG. 4D, in an organic electroluminescent device 114, the organic light emitting layer 30 is provided on the whole of the first electrode 10. In the organic electroluminescent device 110, the organic light emitting layer 30 is patterned into substantially the same pattern shape as the pattern shape of the second electrode 20. As shown in the organic electroluminescent device 114, the organic light emitting layer 30 may not be patterned. In this case, a part of the organic light emitting layer 30, which overlaps with the conductive part 20a when being projected onto the X-Y plane, will form an emission area EA. In the organic electroluminescent device 114, the organic light emitting layer 30 has light permeability.

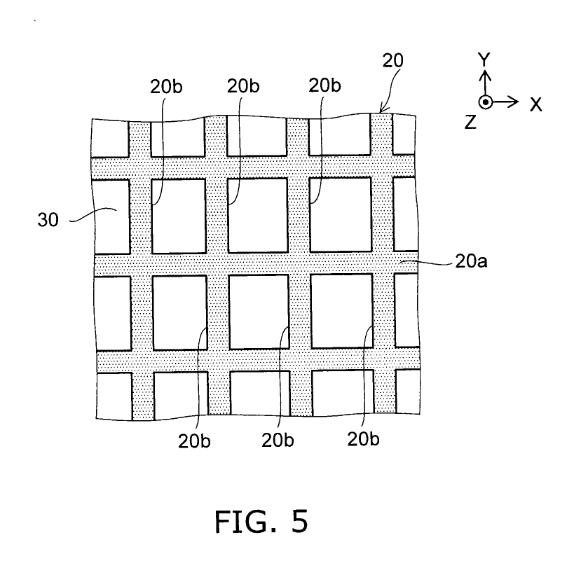

FIG. 5 is a schematic plan view showing part of another organic electroluminescent device according to the first embodiment.

As shown in FIG. 5, the second electrode 20 may be the shape of a grating. In this example, each of the plurality of openings 20b is arranged side by side in the Y-axis direction as well as being arranged side by side in the X-axis direction. Namely, each of the plurality of openings 20b is arranged side by side in the X-axis direction and in the Y-axis direction in the form of a two-dimensional matrix. The shape of each of the plurality of openings 20b projected onto the X-Y plane is, for example, the shape of a square. Because of this, when being projected onto the X-Y plane, the conductive parts 20a has the shape of a grating. In this example, the pattern shape of the second electrode 20 has the shape of a grating. As described above, the pattern shape of the second electrode 20 is not limited to the shape of a stripe and may be the shape of a grating.

In the case where the conductive part 20a is formed into the shape of a grating, for example, as in the organic electroluminescent device 114, the organic light emitting layer is provided on the whole of the first electrode 10. Furthermore, the organic light emitting layer 30 is formed into the pattern shape in the form of a grating like the conductive part 20a. Because of this, it is possible to suppress a short circuit between the first electrode 10 and the second electrode 20.

In this example, the shape of the opening 20b projected onto the X-Y plane has the shape of a square. The shape of the opening 20b is not limited to the shape of a square and may be the shape of, for example, a circle, ellipse, or polygon. The shape of the opening 20b may be any shape. In the specification of the application, the “shape of a grating” includes the shape whose opening is any shape, in addition to the shape whose opening has the shape of a square. For example, the shape of a honeycomb is included in the “shape of a grating”. Namely, the pattern shape of the second electrode 20 may be the shape of a honeycomb.

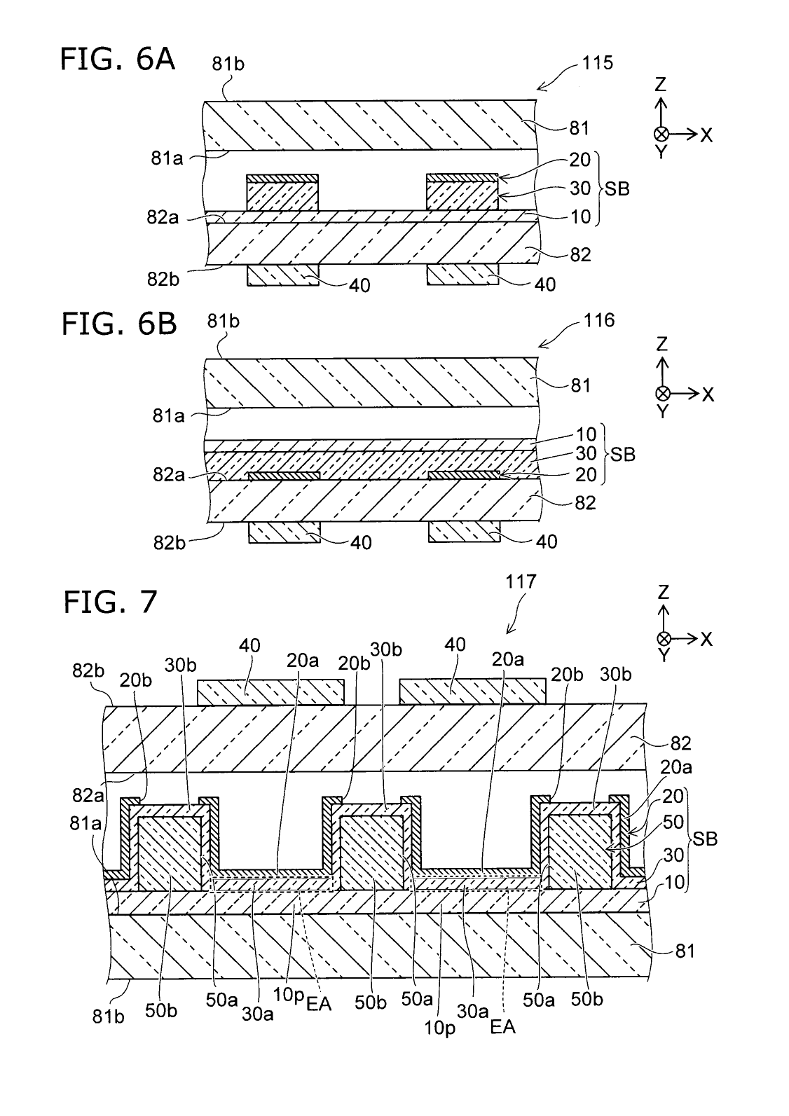

FIGS. 6A and 6B are schematic cross-sectional views showing other organic electroluminescent devices according to the first embodiment.

As shown in FIG. 6A, in an organic electroluminescent device 115, the stacked body SB is provided on the third major surface 82a of the second substrate 82. As described above, the stacked body SB may be provided on the second substrate 82. In this case, the light scattering part 40 is provided, for example, on the fourth major surface 82b. As described above, the light scattering part 40 may also be provided on the substrate on the side on which the stacked body SB is provided. In the organic electroluminescent device 115 also, it is possible to enhance the visibility of a transmitted image.

As shown in FIG. 6B, in an organic electroluminescent device 116, the second substrate 82, the second electrode 20, the organic light emitting layer 30, the first electrode 10, and the first substrate 81 are stacked in this order. Namely, in the organic electroluminescent device 116, the stacking order of the stacked body SB is opposite to the stacking order in the organic electroluminescent device 115. As described above, the stacking order of the stacked body SB may be the order of the second electrode 20, the organic light emitting layer 30, and the first electrode 10. In the configuration in which the stacked body SB is provided on the first substrate 81, the stacking order of the stacked body SB may be changed into the order of the second electrode 20, the organic light emitting layer 30, and the first electrode 10.

FIG. 7 is a schematic cross-sectional view showing another organic electroluminescent device according to the first embodiment.

As shown in FIG. 7, in an organic electroluminescent device 117, the stacked body SB further includes an insulating layer 50.

The insulating layer 50 is provided between the first electrode 10 and the organic light emitting layer 30. The insulating layer 50 is provided, for example, on the first electrode 10. The insulating layer 50 has an opening 50a and an insulating part 50b. The insulating layer 50 has, for example, a plurality of openings 50a and a plurality of insulating parts 50b. Each of the plurality of openings 50a extends in a first direction and is arranged side by side in a second direction perpendicular to the first direction. In this example, each of the plurality of openings 50a extends in the Y-axis direction and is arranged side by side in the X-axis direction. Namely, in this example, each of the plurality of openings 50a has the shape of a groove. Each of the plurality of openings 50a exposes part of the first electrode 10. In this example, a plurality of parts of the first electrode 10 are exposed by each of the plurality of openings 50a. In the following, the part of the first electrode 10, which is exposed by the opening 50a, is referred to as an exposed part 10p. Each of the plurality of insulating parts 50b is disposed between each of the plurality of openings 50a. In this example, each of the plurality of insulating parts 50b extends in the Y-axis direction.

In this example, the organic light emitting layer 30 is provided on the insulating layer 50. The organic light emitting layer 30 has a first part 30a provided on the exposed part 10p of the first electrode 10 and a second part 30b provided on the insulating layer 50. The second part 30b is a part of the organic light emitting layer 30, which is provided on the insulating part 50b. The organic light emitting layer 30 is provided, for example, successively on each of the plurality of insulating parts 50b and on each of the plurality of exposed parts 10p. The organic light emitting layer 30 has light permeability.

The thickness (length along the Z-axis direction) of the organic light emitting layer 30 is smaller than a thickness of the insulating layer 50 (insulating part 50b). A distance in the Z-axis direction between the upper face of the first part 30a of the organic light emitting layer 30 and the upper face of the first electrode 10 is smaller than a distance in the Z-axis direction between the upper face of the insulating part 50b of the insulating layer 50 and the upper face of the first electrode 10. Namely, the upper face of the first part 30a is located below the upper face of the insulating part 50b.

Each of the plurality of conductive parts 20a is disposed in a position that overlaps with each of the plurality of first parts 30a when being projected onto the X-Y plane. In the organic electroluminescent device 117, the part of the organic light emitting layer 30, which is between the exposed part 10p and the conductive part 20a, serves as the emission area EA. Each of the plurality of light scattering parts 40 is disposed in a position that overlaps with each of the plurality of conductive parts 20a when being projected onto the X-Y plane.

In the organic electroluminescent device 117 also, it is possible to enhance the visibility of a transmitted image. Further, in the organic electroluminescent device 117, it is possible to suppress the contact of a mask or the like with the first part 30a serving as the emission area EA of the organic light emitting layer 30 when, for example, forming the second electrode 20. In the organic electroluminescent device 117, it is possible to suppress the damage of the first part 30a serving as the emission area EA of the organic light emitting layer 30 when, for example, forming the second electrode 20 or the like. In the organic electroluminescent device 117, for example, it is possible to enhance yields. In the organic electroluminescent device 117, for example, high reliability is obtained.

For example, an insulating resin material, such as a polyimide resin and an acrylic resin, an insulating inorganic material, such as a silicon oxide film (e.g., SiO₂), a silicon nitride film (e.g., SiN), and a silicon oxynitride film, or the like is used for the insulating layer 50. The materials of the insulating layer 50 are not limited to these materials.

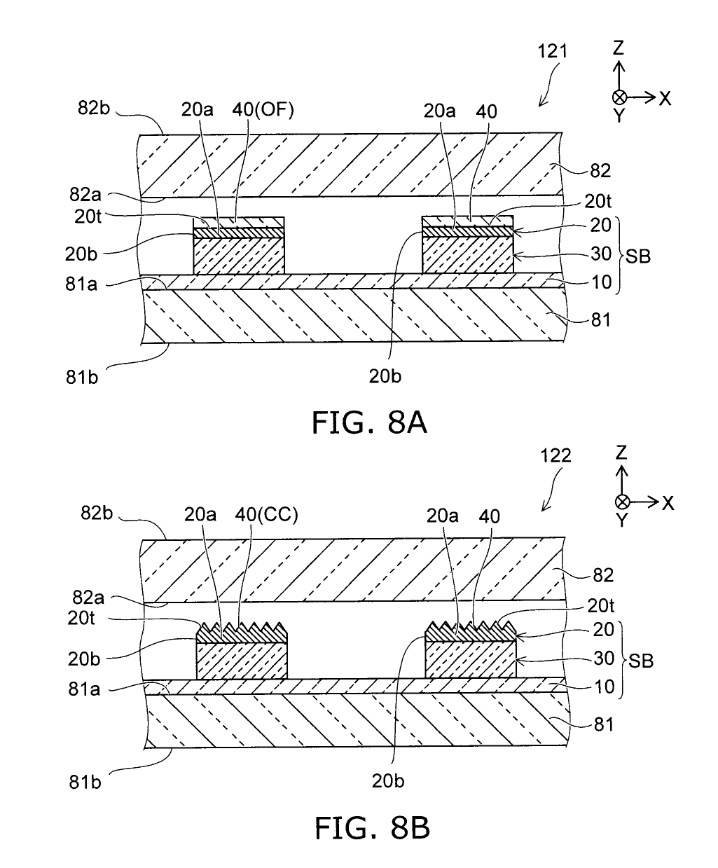

FIGS. 8A and 8B are schematic cross-sectional views showing other organic electroluminescent devices according to the first embodiment.

As shown in FIG. 8A, in an organic electroluminescent device 121, the light scattering part 40 is provided on the conductive part 20a. The organic electroluminescent device 121 includes a plurality of light scattering parts 40. In this example, each of the plurality of light scattering parts 40 is provided on each of the plurality of conductive parts 20a. Each of the plurality of light scattering parts 40 is disposed facing the second substrate 82. The conductive part 20a has an opposing face 20t facing the second substrate 82. The light scattering part 40 is provided, for example, on the opposing face 20t. In this example, the light scattering part 40 is, for example, the optical film OF.

Also in the organic electroluminescent device 121, the light that enters from the side of the second substrate 82 and is reflected from the conductive part 20a scatters at the light scattering part 40. Because of this, also in the organic electroluminescent device 121, it is possible to enhance the visibility of a transmitted image.

As shown in FIG. 8B, in an organic electroluminescent device 122, the light scattering part 40 is the concave and convex part CC provided on the opposing face 20t itself of the conductive part 20a. As described above, in the case where the light scattering part 40 is provided on the conductive part 20a, the light scattering part 40 may be the concave and convex part CC provided on the opposing face 20t itself.

In the case where the light scattering part 40 is provided on the conductive part 20a, the conductive part 20a may have the shape of a grating. The stacked body SB may be provided on the second substrate 82. The stacking order of the stacked body SB may be opposite. For example, in the case where the light scattering part 40 is formed into the concave and convex part CC, in the conductive part 20a, the light scattering part 40 may be provided both on the face facing the second substrate 82 and on the face facing the first substrate 81. For example, the light scattering part 40 may be provided both on the conductive part 20a and on the second substrate 82.

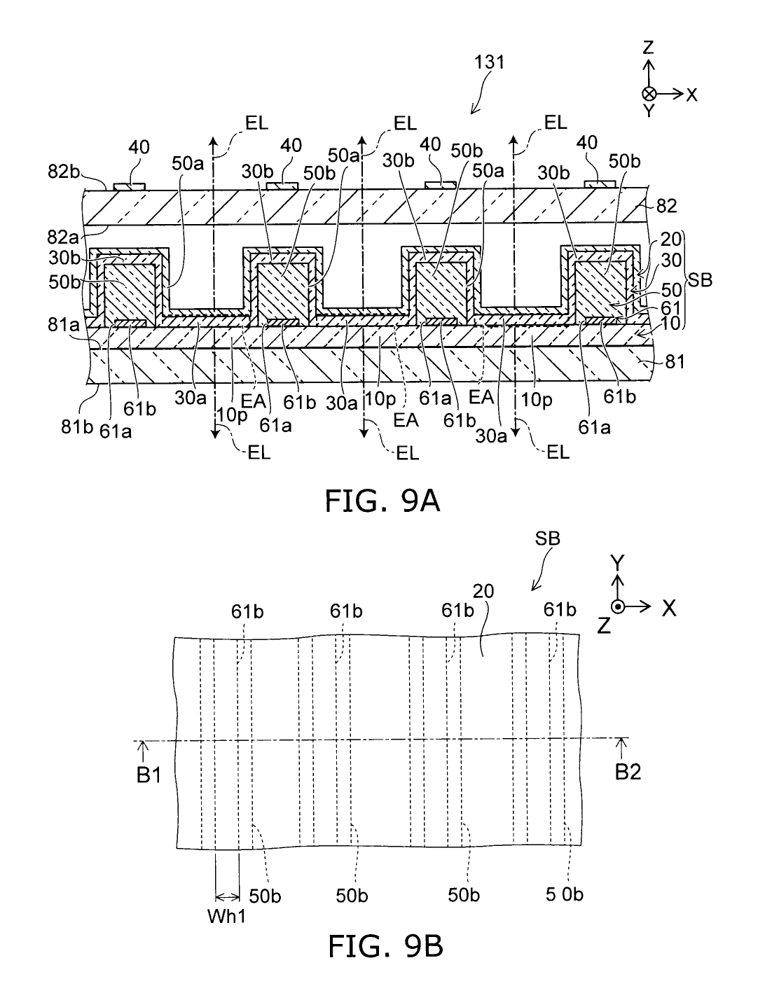

FIGS. 9A and 9B are schematic views showing another organic electroluminescent device according to the first embodiment.

FIG. 9A is a schematic cross-sectional view of an organic electroluminescent device 131 and FIG. 9B is a schematic plan view of the stacked body SB of the organic electroluminescent device 131. FIG. 9A is a B1-B2 line cross-section of FIG. 9B.

As shown in FIGS. 9A and 9B, in the organic electroluminescent device 131, the second electrode 20 is provided on the organic light emitting layer 30. For example, the second electrode 20 is provided on the whole of the organic light emitting layer 30. In this example, the second electrode 20 has light permeability. The second electrode 20 is, for example, transparent.

Because of this, in the organic electroluminescent device 131, when a voltage is applied to the organic light emitting layer 30 via the first electrode 10 and the second electrode 20, the emission light EL emitted from the emission area EA is emitted to the outside of the organic electroluminescent device 131 via the first electrode 10 and at the same time, the emission light EL is emitted to the outside of the organic electroluminescent device 131 via the second electrode 20. Namely, the organic electroluminescent device 131 is of a double-sided light emission type.

In the organic electroluminescent device 131, the stacked body SB further includes a first wiring layer 61. The first wiring layer 61 is provided between the first electrode 10 and the insulating layer 50. The first wiring layer 61 has an opening 61a and a wiring part 61b. The opening 61a exposes part of the first electrode 10. The first wiring layer 61 has, for example, a plurality of openings 61a and a plurality of wiring parts 61b. In this example, each of the plurality of openings 61a extends in the Y-axis direction and is arranged side by side in the X-axis direction. The plurality of wiring parts 61b are provided between each of the plurality of openings 61a. Namely, in this example, the first wiring layer 61 has a pattern shape in the form of a stripe. Each of the plurality of wiring parts 61b is disposed in a position that overlaps with each of the plurality of insulating parts 50b when, for example, being projected onto the X-Y plane. Each of the plurality of wiring parts 61b may not necessarily overlap with each of the plurality of insulating parts 50b.

The first wiring layer 61 is electrically connected to the first electrode 10. The first wiring layer 61 makes contact with, for example, the first electrode 10. A conductivity of the first wiring layer 61 is higher than a conductivity of the first electrode 10. The wiring part 61b has light reflective properties. A light reflectance of the wiring part 61b is higher than the light reflectance of the first electrode 10. The wiring part 61b is, for example, a metal wire. The first wiring layer functions as, for example, an auxiliary electrode that transmits a current flowing through the first electrode 10. Because of this, in the organic electroluminescent device 131, for example, it is possible to make more uniform the amount of current that flows in a direction parallel to the film face of the first electrode 10. For example, it is possible to make more uniform in-plane light emission luminance.

A width Wh1 (length in the X-axis direction) of the wiring part 61b is, for example, not less than 0.5 μm and not more than 400 μm. In this example, a pitch of each of the plurality of wiring parts 61b is substantially the same as a pitch of each of the plurality of insulating parts 50b. The pitch of each of the plurality of wiring parts 61b may be, for example, an integer multiple of the pitch of each of the plurality of insulating parts 50b. Namely, the wiring part 61b may also be provided for every two or three insulating parts 50b. The first wiring layer 61 may also be provided between the first electrode 10 and the first substrate 81. The pattern shape of the first wiring layer 61 may be the shape of a grating.

In the organic electroluminescent device 131, the light scattering part 40 is provided on the second substrate 82. In this example, the light scattering part 40 is disposed in a position that overlaps with the wiring part 61b when being projected onto the X-Y plane. The organic electroluminescent device 131 has a plurality of light scattering parts 40. Each of the plurality of light scattering parts 40 is disposed in a position that overlaps with each of the plurality of wiring parts 61b. In this example, the plurality of light scattering parts 40 are provided on the fourth major surface 82b of the second substrate 82. The plurality of light scattering parts 40 may be provided on the third major surface 82a.

In the organic electroluminescent device 131, the light that enters from the side of the second substrate 82 and is reflected from the wiring part 61b scatters at the light scattering part 40. Because of this, in the organic electroluminescent device 131, for example, it is possible to suppress lowering of the visibility of a transmitted image caused by the light reflected from the wiring part 61b of the first wiring layer 61. In the organic electroluminescent device 131 also, it is possible to enhance the visibility of a transmitted image. Also in this case, the light scattering part 40 may be the optical film OF or the concave and convex part CC.

As the light transmissive second electrode 20, for example, it is possible to use the materials described in relation to the first electrode 10. Furthermore, as the light transmissive second electrode 20, for example, metal materials, such as MgAg, may be used. In the case of the metal material, the thickness of the second electrode 20 is set to a thickness not less than 5 nm and not more than 20 nm. Because of this, it is possible to obtain appropriate light permeability.

The first wiring layer 61 contains at least any one of elements selected from the group consisting of, for example, Mo, Ta, Nb, Al, Ni, and Ti. It is possible to form the first wiring layer 61 as a mixed film containing an element selected from this group. It is possible to form the first wiring layer 61 as a stacked film containing those elements. As the first wiring layer 61, for example, it is possible to use a stacked film of Nb/Mo/Al/Mo/Nb. The first wiring layer 61 functions as, for example, an auxiliary electrode that suppresses a potential drop of the first electrode 10. It is possible for the first wiring layer 61 to function as a lead electrode for supply of current. The materials of the first wiring layer 61 are not limited to these materials.

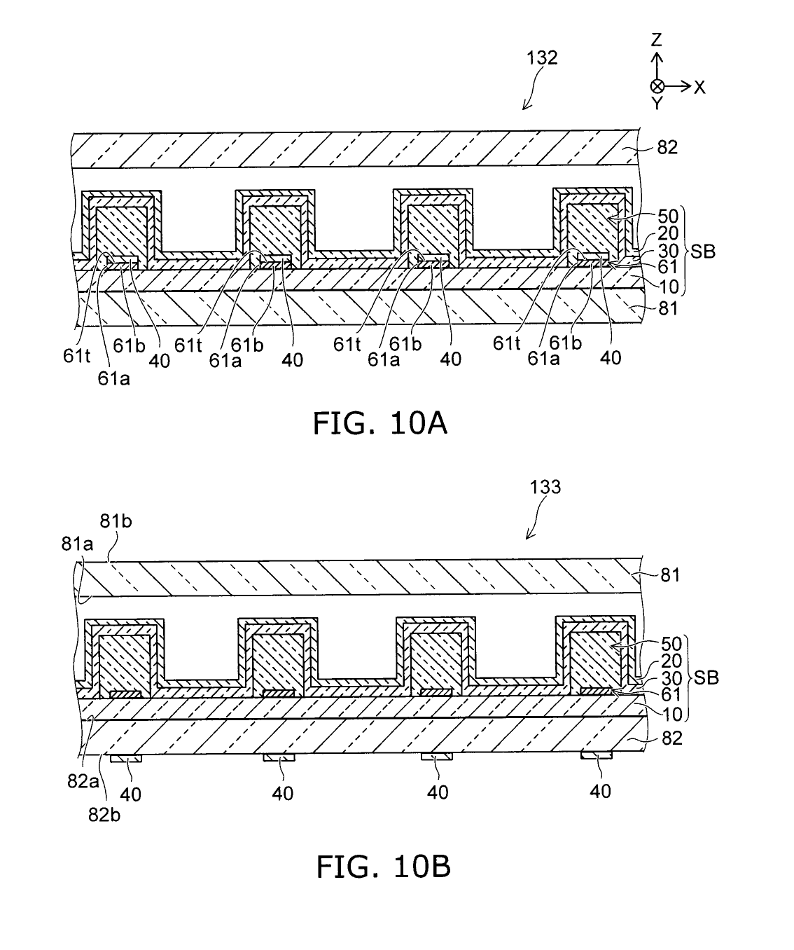

FIGS. 10A and 10B are schematic cross-sectional views showing other organic electroluminescent devices according to the first embodiment.

As shown in FIG. 10A, in an organic electroluminescent device 132, the light scattering part 40 is provided on the wiring part 61b of the first wiring layer 61. The light scattering part 40 is provided on the wiring part 61b facing the second substrate 82. The wiring part 61b has, for example, an opposing face 61t facing the second substrate 82. The light scattering part 40 is provided, for example, on the opposing face 61t of the wiring part 61b. The organic electroluminescent device 132 has a plurality of light scattering parts 40. Each of the plurality of light scattering parts 40 is provided on each of the plurality of wiring parts 61b. Also in the organic electroluminescent device 132, it is possible to suppress lowering of the visibility of a transmitted image resulting from the light caused by the wiring part 61b of the first wiring layer 61. It is possible to enhance the visibility of a transmitted image. As described above, the light scattering part 40 may be provided on the wiring part 61b.

As shown in FIG. 10B, in an organic electroluminescent device 133, the stacked body SB is provided on the third major surface 82a of the second substrate 82. In this case, the light scattering part 40 is provided, for example, on the fourth major surface 82b. In the organic electroluminescent device 133 also, it is possible to suppress lowering of the visibility of a transmitted image caused by the light reflected from the wiring part 61b of the first wiring layer 61. It is possible to enhance the visibility of a transmitted image. The light scattering part 40 may be provided both on the first substrate 81 and on the second substrate 82.

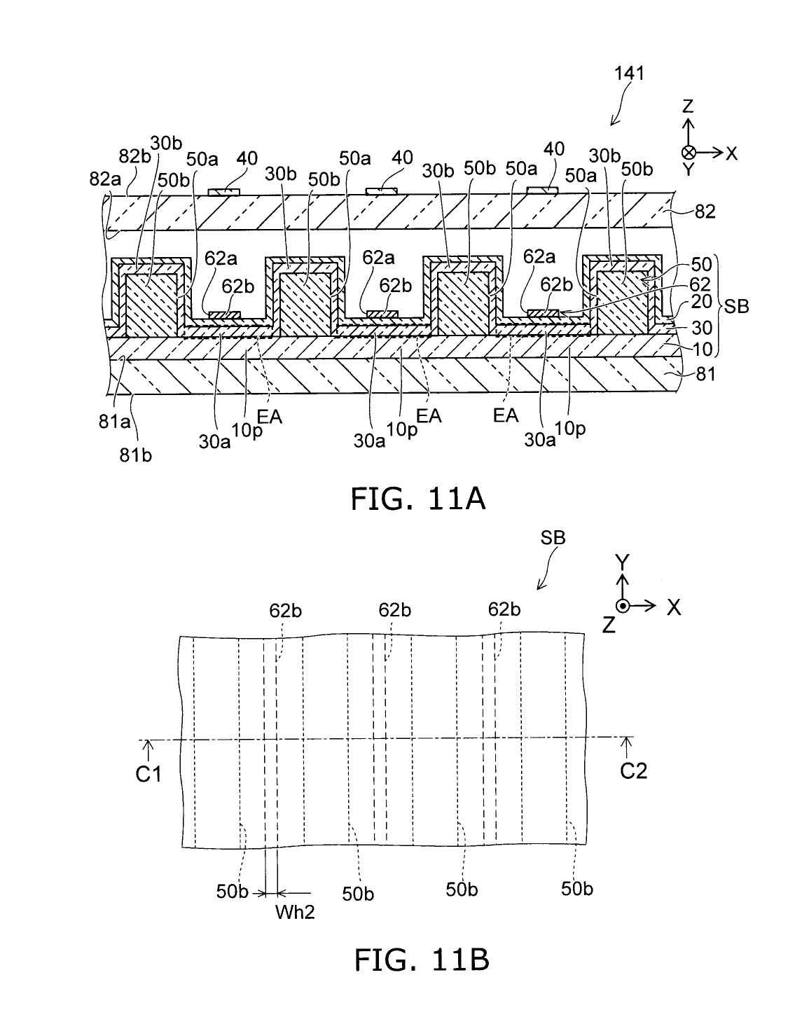

FIGS. 11A and 11B are schematic diagrams showing another organic electroluminescent device according to the first embodiment.

FIG. 11A is a schematic cross-sectional view of an organic electroluminescent device 141 and FIG. 11B is a schematic plan view of the organic electroluminescent device 141. FIG. 11A is a C1-C2 line cross-section of FIG. 11B.

As shown in FIGS. 11A and 11B, in the organic electroluminescent device 141, the stacked body SB further includes a second wiring layer 62. In this example, the second electrode 20 is provided between the organic light emitting layer 30 and the second wiring layer 62. Namely, the second wiring layer 62 is provided on the second electrode 20.

The second wiring layer 62 has an opening 62a and a wiring part 62b. The opening 62a exposes part of the second electrode 20. The second wiring layer 62 has, for example, a plurality of openings 62a and a plurality of wiring parts 62b. In this example, each of the plurality of openings 62a extends in the Y-axis direction and is arranged side by side in the X-axis direction. The plurality of wiring parts 62b are provided between each of the plurality of openings 62a. Namely, in this example, the second wiring layer 62 has a pattern shape in the form of a stripe. In this example, each of the plurality of wiring parts 62b is disposed in a position that does not overlap with each of the plurality of insulating parts 50b when being projected onto the X-Y plane. Each of the plurality of wiring parts 62b may be disposed in a position that overlaps with each of the plurality of insulating parts 50b when being projected onto the X-Y plane.

The second wiring layer 62 is electrically connected to the second electrode 20. The second wiring layer 62 makes contact with, for example, the second electrode 20. A conductivity of the second wiring layer 62 is higher than a conductivity of the second electrode 20. The wiring part 62b has light reflective properties. A light reflectance of the wiring part 62b is higher than a light reflectance of the second electrode 20. The wiring part 62b is, for example, a metal wire. The second wiring layer 62 functions as, for example, an auxiliary electrode that transmits a current flowing through the second electrode 20. Because of this, in the organic electroluminescent device 141, for example, it is possible to make more uniform the amount of current that flows in the X-Y plane direction of the second electrode 20. For example, it is possible to make more uniform the in-plane light emission luminance.

A width Wh2 (length in the X-axis direction) of the wiring part 62b is, for example, not less than 0.5 μm and not more 3o than 400 μm. In this example, each of the plurality of wiring parts 62b is disposed in a position that overlaps with each of the plurality of first parts 30a when being projected onto the X-Y plane. The wiring part 62b may be provided, for example, at every two or every three first parts 30a.

The second wiring layer 62 may be provided, for example, between the second electrode 20 and the organic light emitting layer 30. The pattern shape of the second wiring layer 62 may be the shape of a grating. As the second wiring layer 62, for example, it is possible to use the materials described in relation to the first wiring layer 61.

In the organic electroluminescent device 141, the light scattering part 40 is provided on the second substrate 82. In this example, the light scattering part 40 is disposed in a position that overlaps with the wiring part 62b when being projected onto the X-Y plane. The organic electroluminescent device 141 has a plurality of light scattering parts 40. Each of the plurality of light scattering parts 40 is disposed in a position that overlaps with each of the plurality of wiring parts 62b. In this example, the plurality of light scattering parts 40 are provided on the fourth major surface 82b of the second substrate 82. The plurality of light scattering parts 40 may be provided on the third major surface 82a.

In the organic electroluminescent device 141, the light that enters from the side of the second substrate 82 and is reflected from the wiring part 62b scatters at the light scattering part 40. Because of this, in the organic electroluminescent device 141, it is possible to suppress lowering of the visibility of a transmitted image caused by the light reflected from the wiring part 62b of the second wiring layer 62. In the organic electroluminescent device 141 also, it is possible to enhance the visibility of a transmitted image. In this case also, the light scattering part 40 may be the optical film OF or the concave and convex part CC.

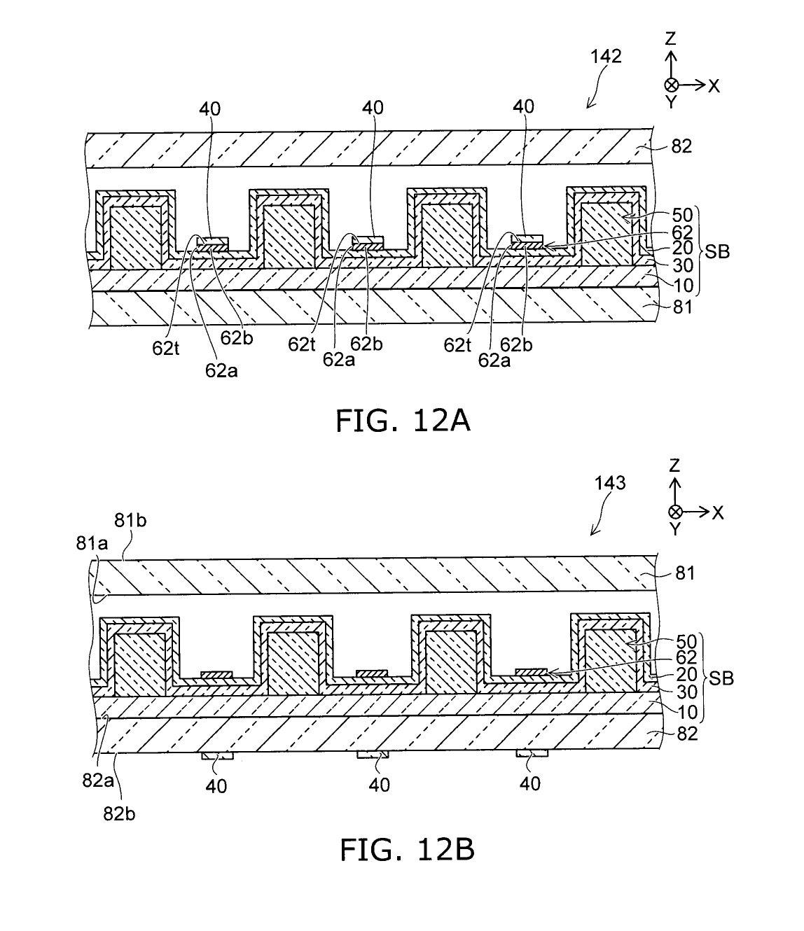

FIGS. 12A and 12B are schematic cross-sectional views showing other organic electroluminescent devices according to the first embodiment.

As shown in FIG. 12A, in an organic electroluminescent device 142, the light scattering part 40 is provided on the wiring part 62b of the second wiring layer 62. The light scattering part 40 is provided on the wiring part 62b facing the second substrate 82. The wiring part 62b has, for example, an opposing face 62t facing the second substrate 82. The light scattering part 40 is provided, for example, on the opposing face 62t of the wiring part 62b. The organic electroluminescent device 142 has a plurality of light scattering parts 40. Each of the plurality of light scattering parts 40 is provided on each of the plurality of wiring parts 62b. In the organic electroluminescent device 142 also, it is possible to suppress lowering of the visibility of a transmitted image caused by the light reflected from the wiring part 62b of the second wiring layer 62. It is possible to enhance the visibility of a transmitted image. As described above, the light scattering part 40 may be provided on the wiring part 62b.

As shown in FIG. 12B, in an organic electroluminescent device 143, the stacked body SB is provided on the third major surface 82a of the second substrate 82. In this case, the light scattering part 40 is provided, for example, on the fourth major surface 82b. In the organic electroluminescent device 143 also, it is possible to suppress lowering of the visibility of a transmitted image caused by the light reflected from the wiring part 62b of the second wiring layer 62. It is possible to enhance the visibility of a transmitted image. The light scattering part 40 may be provided both on the first substrate 81 and on the second substrate 82.

The stacked body SB may include the first wiring layer 61 and the second wiring layer 62. In this case, for example, in the second substrate 82, each of the plurality of light scattering parts 40 may be provided in a position that overlaps with each of the wiring part 61b and the wiring part 62b when being projected onto the X-Y plane. Because of this, for example, it is possible to lowering of the visibility of a transmitted image caused by the light reflected from each of the wiring part 61b and the wiring part 62b.

### Second Embodiment

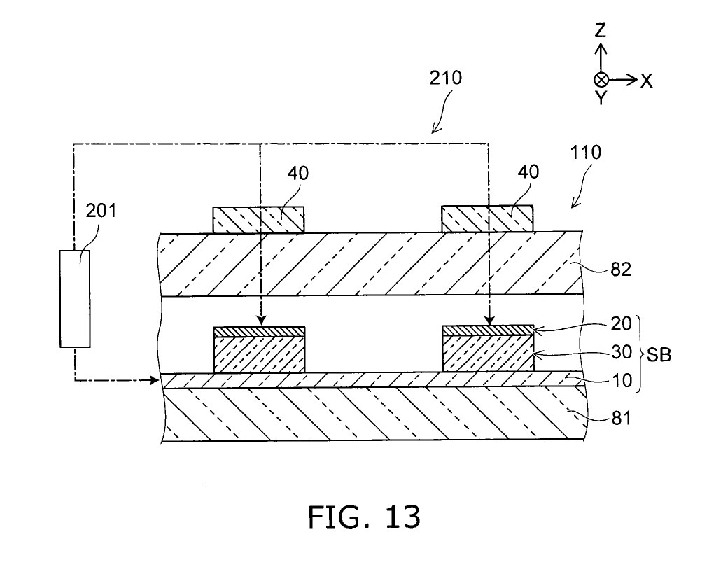

FIG. 13 is a schematic diagram showing an illumination apparatus according to a second embodiment.

As shown in FIG. 13, an illumination apparatus 210 according to the embodiment includes the organic electroluminescent device (e.g., the organic electroluminescent device 110) according to the first embodiment and a power source 201.

The power source 201 is electrically connected to the first electrode 10 and the second electrode 20. The power source 201 supplies a current to the organic light emitting layer 30 via the first electrode 10 and the second electrode 20.

According to the illumination apparatus 210 according to the embodiment, it is possible to provide an illumination apparatus with high visibility of a transmitted image.

### Third Embodiment

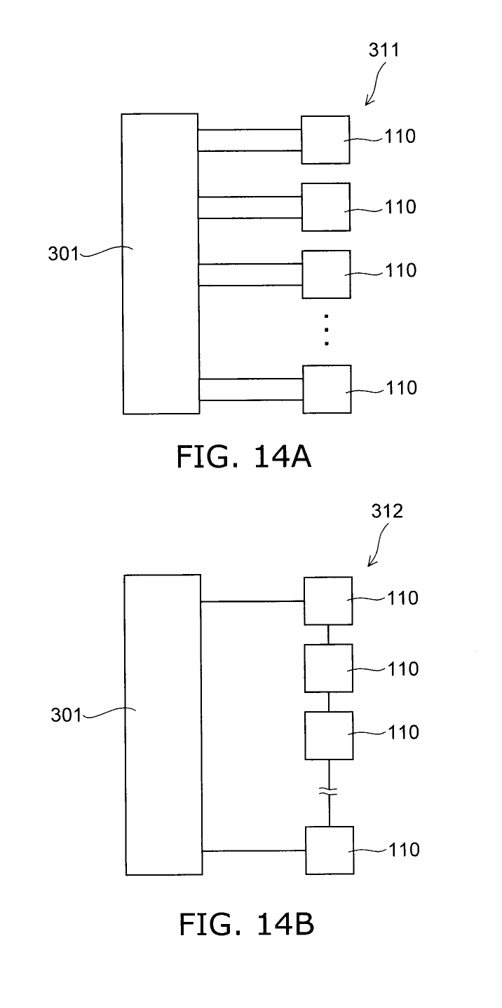

FIGS. 14A and 14B are schematic diagrams showing an illumination system according to a third embodiment.

As shown in FIG. 14A, an illumination system 311 according to the embodiment includes a plurality of organic electroluminescent devices (e.g., the organic electroluminescent device 110) according to the first embodiment and a controller 301.

The controller 301 is electrically connected to each of the plurality of organic electroluminescent devices 110 and controls turning on and off of each of the plurality of organic electroluminescent devices 110. The controller 301 is electrically connected to, for example, the first electrode 10 and the second electrode 20 of each of the plurality of organic electroluminescent devices 110. Because of this, the controller 301 controls turning on and off of each of the plurality of organic electroluminescent devices 110 individually.

As shown in FIG. 14B, in an illumination system 312, each of the plurality of organic electroluminescent devices 110 is connected in series. The controller 301 is electrically connected to the first electrode 10 of one of the plurality of organic electroluminescent devices 110. Then, the controller 301 is electrically connected to the second electrode 20 of another of the plurality of organic electroluminescent devices 110. Because of this, the controller 301 controls turning on and off of each of the plurality of organic electroluminescent devices 110 together. As described above, the controller 301 may control turning on and off of each of the plurality of organic electroluminescent devices 110 individually or together.

According to the illumination systems 311 and 312 according to the embodiment, it is possible to provide an illumination system with high visibility of a transmitted image.

According to the embodiments, an organic electroluminescent device, an illumination apparatus, and an illumination system each with high visibility of a transmitted image are provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components included in organic electroluminescent devices, illumination apparatuses, and illumination systems such as first substrates, second substrates, stacked bodies, first electrodes, second electrodes, organic light emitting layers, wiring layers, openings, conductive parts, wiring parts, light scattering parts, power sources, controllers, etc., from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Moreover, all organic electroluminescent devices, illumination apparatuses, and illumination systems practicable by an appropriate design modification by one skilled in the art based on the organic electroluminescent devices, illumination apparatuses, and illumination systems described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An organic electroluminescent device comprising:
a first substrate having light permeability;
a second substrate having light permeability; and
a stacked body provided between the first substrate and the second substrate, the stacked body including:
a first electrode having light permeability;
a second electrode including an opening and a conductive part, the conductive part being light reflective, the second electrode being stacked on the first electrode in a stacking direction of the first substrate and the second substrate; and
an organic light emitting layer provided between the first electrode and the second electrode,
the second substrate including a light scattering part overlapping with the conductive part when projected onto a plane perpendicular to the stacking direction.

2. An organic electroluminescent device comprising:
a first substrate having light permeability;
a second substrate having light permeability; and
a stacked body provided between the first substrate and the second substrate, the stacked body including:
a first electrode having light permeability;
a second electrode including an opening and a conductive part, the conductive part being light reflective, the second electrode being stacked on the first electrode in a stacking direction of the first substrate and the second substrate; and
an organic light emitting layer provided between the first electrode and the second electrode,
the conductive part including a light scattering part facing the second substrate.

3. An organic electroluminescent device comprising:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the wiring layer being provided between the first electrode and the organic light emitting layer,
the second substrate including a light scattering part overlapping with the wiring part when projected onto a plane perpendicular to the stacking direction.

4. An organic electroluminescent device comprising:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the wiring layer being provided between the first electrode and the organic light emitting layer,
the wiring part including a light scattering part facing the second substrate.

5. An organic electroluminescent device comprising:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the second electrode being disposed between the wiring layer and the organic light emitting layer,
the second substrate including a light scattering part overlapping with the wiring part when projected onto a plane perpendicular to the stacking direction.

6. An organic electroluminescent device comprising:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the second electrode being disposed between the wiring layer and the organic light emitting layer,
the wiring part including a light scattering part facing the second substrate.

7. The device according to claim 1, wherein
the light scattering part is an optical film having light permeability and light scattering properties.

8. The device according to claim 1, wherein
the light scattering part is a concave and convex part provided on the second substrate.

9. An illumination apparatus comprising:
an organic electroluminescent device including:
a first substrate having light permeability;
a second substrate having light permeability; and
a stacked body provided between the first substrate and the second substrate, the stacked body including:
a first electrode having light permeability;
a second electrode including an opening and a conductive part, the conductive part being light reflective, the second electrode being stacked on the first electrode in a stacking direction of the first substrate and the second substrate; and
an organic light emitting layer provided between the first electrode and the second electrode; and
a power source electrically connected to the first electrode and the second electrode and supplying a current to the organic light emitting layer via the first electrode and the second electrode,
the second substrate including a light scattering part overlapping with the conductive part when projected onto a plane perpendicular to the stacking direction.

10. An illumination apparatus comprising:
an organic electroluminescent device including:
a first substrate having light permeability;
a second substrate having light permeability; and
a stacked body provided between the first substrate and the second substrate, the stacked body including:
a first electrode having light permeability;
a second electrode including an opening and a conductive part, the conductive part being light reflective, the second electrode being stacked on the first electrode in a stacking direction of the first substrate and the second substrate; and
an organic light emitting layer provided between the first electrode and the second electrode; and
a power source electrically connected to the first electrode and the second electrode and supplying a current to the organic light emitting layer via the first electrode and the second electrode,
the conductive part including a light scattering part facing the second substrate.

11. An illumination apparatus comprising:
an organic electroluminescent device including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the wiring layer being provided between the first electrode and the organic light emitting layer; and
a power source electrically connected to the first electrode and the second electrode and supplying a current to the organic light emitting layer via the first electrode and the second electrode,
the second substrate including a light scattering part overlapping with the wiring part when projected onto a plane perpendicular to the stacking direction.

12. An illumination apparatus comprising:
an organic electroluminescent device including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the wiring layer being provided between the first electrode and the organic light emitting layer; and
a power source electrically connected to the first electrode and the second electrode and supplying a current to the organic light emitting layer via the first electrode and the second electrode,
the wiring part including a light scattering part facing the second substrate.

13. An illumination apparatus comprising:
an organic electroluminescent device including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the second electrode being disposed between the wiring layer and the organic light emitting layer; and
a power source electrically connected to the first electrode and the second electrode and supplying a current to the organic light emitting layer via the first electrode and the second electrode,
the second substrate including a light scattering part overlapping with the wiring part when projected onto a plane perpendicular to the stacking direction.

14. An illumination apparatus comprising:
an organic electroluminescent device including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the second electrode being disposed between the wiring layer and the organic light emitting layer; and
a power source electrically connected to the first electrode and the second electrode and supplying a current to the organic light emitting layer via the first electrode and the second electrode,
the wiring part including a light scattering part facing the second substrate.

15. An illumination system comprising:
a plurality of organic electroluminescent devices, each of the organic electroluminescent devices including:
a first substrate having light permeability;
a second substrate having light permeability; and
a stacked body provided between the first substrate and the second substrate, the stacked body including:
a first electrode having light permeability;
a second electrode including an opening and a conductive part, the conductive part being light reflective, the second electrode being stacked on the first electrode in a stacking direction of the first substrate and the second substrate; and
an organic light emitting layer provided between the first electrode and the second electrode; and
a controller electrically connected to each of the organic electroluminescent devices and controlling turning on and off of each of the organic electroluminescent devices,
the second substrate including a light scattering part overlapping with the conductive part when projected onto a plane perpendicular to the stacking direction.

16. An illumination system comprising:
a plurality of organic electroluminescent devices, each of the organic electroluminescent devices including:
a first substrate having light permeability;
a second substrate having light permeability; and
a stacked body provided between the first substrate and the second substrate, the stacked body including:
a first electrode having light permeability;
a second electrode including an opening and a conductive part, the conductive part being light reflective, the second electrode being stacked on the first electrode in a stacking direction of the first substrate and the second substrate; and
an organic light emitting layer provided between the first electrode and the second electrode; and
a controller electrically connected to each of the organic electroluminescent devices and controlling turning on and off of each of the organic electroluminescent devices,
the conductive part including a light scattering part facing the second substrate.

17. An illumination system comprising:
a plurality of organic electroluminescent devices, each of the organic electroluminescent devices including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the wiring layer being provided between the first electrode and the organic light emitting layer; and
a controller electrically connected to each of the organic electroluminescent devices and controlling turning on and off of each of the organic electroluminescent devices,
the second substrate including a light scattering part overlapping with the wiring part when projected onto a plane perpendicular to the stacking direction.

18. An illumination system comprising:
a plurality of organic electroluminescent devices, each of the organic electroluminescent devices including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the wiring layer being provided between the first electrode and the organic light emitting layer; and
a controller electrically connected to each of the organic electroluminescent devices and controlling turning on and off of each of the organic electroluminescent devices,
the wiring part including a light scattering part facing the second substrate.

19. An illumination system comprising:
a plurality of organic electroluminescent devices, each of the organic electroluminescent devices including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the second electrode being disposed between the wiring layer and the organic light emitting layer; and
a controller electrically connected to each of the organic electroluminescent devices and controlling turning on and off of each of the organic electroluminescent devices,
the second substrate including a light scattering part overlapping with the wiring part when projected onto a plane perpendicular to the stacking direction.

20. An illumination system comprising:
a plurality of organic electroluminescent devices, each of the organic electroluminescent devices including:
a first substrate having light permeability;
a second substrate having light permeability; and
a stacked body provided between the first substrate and the second substrate, the stacked body including:
a first electrode having light permeability;
a second electrode stacked on the first electrode in a stacking direction of the first substrate and the second substrate, the second electrode having light permeability;
an organic light emitting layer provided between the first electrode and the second electrode; and
a wiring layer including an opening and a wiring part, the wiring part being light reflective, the second electrode being disposed between the wiring layer and the organic light emitting layer; and
a controller electrically connected to each of the organic electroluminescent devices and controlling turning on and off of each of the organic electroluminescent devices,
the wiring part including a light scattering part facing the second substrate.
